(19) United States
(12) Patent Application Publication
(10) Pub. No.: US 2024/0332258 A1
(43) Pub. Date: Oct. 3, 2024

(54) SEMICONDUCTOR DEVICE AND METHOD FOR FABRICATING THE SAME

(71) Applicant: SK hynix Inc., Gyeonggi-do (KR)

(72) Inventor: Da Il RIM, Gyeonggi-do (KR)

(21) Appl. No.: 18/494,557

(22) Filed: Oct. 25, 2023

(30) Foreign Application Priority Data
Mar. 27, 2023 (KR) 10-2023-0039655

(51) Int. Cl. H01L 25/065; H01L 23/00; H01L 23/528

(52) U.S. Cl. CPC H01L 25/0657; H01L 23/5283; H01L 24/05; H01L 24/80; H01L 2224/05093; H01L 2224/05647; H01L 2224/80895; H01L 2225/06544; H01L 2924/351

(57) ABSTRACT

A semiconductor device may include: a lower semiconductor structure including a lower semiconductor substrate including a first region and a second region, a lower circuit structure disposed in the first region over the lower semiconductor substrate, a lower bonding pad disposed over the lower circuit structure and connected thereto, and a dummy conductive pattern disposed in the second region over the lower semiconductor substrate; an upper semiconductor structure including an upper semiconductor substrate disposed over the lower semiconductor structure and including the first region and the second region, an upper circuit structure disposed in the first region under the upper semiconductor substrate, and an upper bonding pad disposed under the upper circuit structure and connected thereto while being bonded to the lower bonding pad; a through electrode; and a dummy through electrode passing through the upper semiconductor structure and connected to the dummy conductive pattern.

### CROSS-REFERENCE TO RELATED APPLICATION

This application claims priority under 35 U.S.C. § 119 to Korean Patent Application No. 10-2023-0039655 filed on Mar. 27, 2023, which is incorporated herein by reference in its entirety.

### BACKGROUND

### 1. Technical Field

This present invention relates generally to semiconductor technology, and more particularly, to a semiconductor device including two or more semiconductor structures stacked in a vertical direction and electrically connected with each other.

### 2. Related Art

Electronic products require high-capacity data processing even though their volumes are getting smaller. Accordingly, semiconductor structures such as semiconductor chips and wafers used in these electronic products are also required to have a thin thickness and a small size. Furthermore, a form of embedding a plurality of semiconductor structures in one semiconductor device is being implemented.

A plurality of semiconductor structures may be electrically connected to each other while being stacked in a vertical direction. However, further improvements are needed regarding the capacity and reliability of such semiconductor devices.

### SUMMARY

In an embodiment, a semiconductor device may include: a lower semiconductor structure including a lower semiconductor substrate including a first region and a second region adjacent to each other in a horizontal direction, a lower circuit structure disposed in the first region over the lower semiconductor substrate, a lower bonding pad disposed over the lower circuit structure and connected to the lower circuit structure, and a dummy conductive pattern disposed in the second region over the lower semiconductor substrate; an upper semiconductor structure including an upper semiconductor substrate disposed over the lower semiconductor structure and including the first region and the second region, an upper circuit structure disposed in the first region under the upper semiconductor substrate, and an upper bonding pad disposed under the upper circuit structure and connected to the upper circuit structure while being bonded to the lower bonding pad; a through electrode passing through the upper semiconductor substrate and connected to the upper circuit structure; and a dummy through electrode passing through the upper semiconductor structure and connected to the dummy conductive pattern, wherein the dummy through electrode and the dummy conductive pattern are electrically connected to the lower semiconductor substrate through the lower circuit structure.

In another embodiment, a method for fabricating a semiconductor device, may include: providing a lower semiconductor structure including a lower semiconductor substrate including a first region and a second region, a lower circuit structure disposed in the first region over the lower semiconductor substrate, a lower bonding pad disposed over the lower circuit structure and connected the lower circuit structure, and a dummy conductive pattern disposed in the second region over the lower semiconductor substrate; providing an upper semiconductor structure including an upper semiconductor substrate including the first region and the second region, an upper circuit structure disposed in the first region over the upper semiconductor substrate, and an upper bonding pad disposed over the upper circuit structure and connected to the upper circuit structure; bonding the upper bonding pad to the lower bonding pad; etching the upper semiconductor substrate to form a first hole exposing a portion of the upper circuit structure, and etching the upper semiconductor structure to form a second hole exposing the dummy conductive pattern; and forming a through electrode and a dummy through electrode by filling the first hole and the second hole with a conductive material. These and other features and advantages of the present invention will become apparent to the skilled person from the following detailed description and drawings of specific implementations of the invention.

### BRIEF DESCRIPTION OF THE DRAWINGS

FIG. 1 is a simplified cross-sectional view illustrating a lower semiconductor structure according to an embodiment of the present disclosure.

FIG. 2 is a simplified cross-sectional view illustrating an upper semiconductor structure according to an embodiment of the present disclosure.

FIG. 3 is a simplified cross-sectional view illustrating a semiconductor device in a state in which the lower semiconductor structure of FIG. 1 and the upper semiconductor structure of FIG. 2 are stacked.

FIG. 4 is a simplified cross-sectional view illustrating a semiconductor device in a state in which a through electrode and a dummy through electrode are further formed in addition to the semiconductor device of FIG. 3.

FIGS. 5A and 5B are cross-sectional views illustrating a method for fabricating a semiconductor device according to an embodiment of the present disclosure.

FIGS. 6A and 6B are cross-sectional views illustrating a method for fabricating a semiconductor device according to another embodiment of the present disclosure.

FIG. 7 is a simplified cross-sectional view illustrating a semiconductor device according to another embodiment of the present disclosure.

### DETAILED DESCRIPTION

Hereinafter, various embodiments of the disclosure will be described in detail with reference to the accompanying drawings.

The drawings are not necessarily drawn to scale. In some instances, proportions of at least some structures in the drawings may have been exaggerated in order to clearly illustrate certain features of the described embodiments. In presenting a specific example in a drawing or description having two or more layers in a multi-layer structure, the relative positioning relationship of such layers or the sequence of arranging the layers as shown reflects a particular implementation for the described or illustrated example and a different relative positioning relationship or sequence of arranging the layers may be possible. In addition, a described or illustrated example of a multi-layer structure might not reflect all layers present in that particular multilayer structure (e.g., one or more additional layers may be present between two illustrated layers). As a specific example, when a first layer in a described or illustrated multi-layer structure is referred to as being “on” or “over” a second layer or “on” or “over” a substrate, the first layer may be directly formed on the second layer or the substrate but may also represent a structure where one or more other intermediate layers may exist between the first layer and the second layer or the substrate.

In the following description, a semiconductor structure may mean a semiconductor chip, a semiconductor wafer, or the like, including a circuit and/or wiring structure that performs a predetermined function. Also, a semiconductor device may include two or more semiconductor structures that are stacked in a vertical direction and electrically connected to each other. Hereinafter, it will be described in more detail with reference to the drawings.

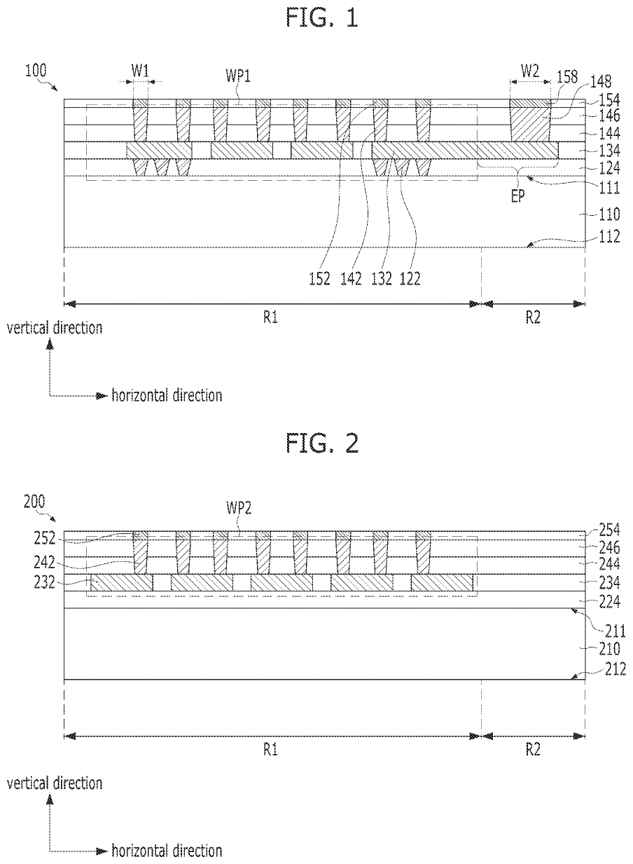

FIG. 1 is a simplified cross-sectional view illustrating a lower semiconductor structure according to an embodiment of the present disclosure.

Referring to FIG. 1, a lower semiconductor structure 100 of an embodiment of the present invention may include a lower semiconductor substrate 110 including a first region R1 and a second region R2, a lower circuit structure WP1 disposed over the first region R1 of the lower semiconductor substrate 110, one or more lower bonding pads 152 connected to the lower circuit structure WP1 over the lower circuit structure WP1, a dummy conductive via 148 disposed over the second region R2 of the lower semiconductor substrate 110 and connected to the lower circuit structure WP1, a dummy conductive pad 158 connected to the dummy conductive via 148 over the dummy conductive via 148, and a lower insulating layer 154 filled between the lower bonding pads 152 and between the lower bonding pad 152 and the dummy conductive pad 158.

The lower semiconductor substrate 110 may include a semiconductor material such as silicon or germanium, and may have a first surface 111 and a second surface 112 opposite to each other in a thickness (or height) direction of the lower semiconductor substrate 110, and a side surface. The first surface 111 may correspond to a front surface and/or an active surface on which the lower circuit structure WP1 is disposed, and the second surface 112 may correspond to a rear surface and/or an inactive surface positioned opposite to the front surface and/or the active surface. Hereinafter, for convenience of description, a direction substantially parallel to the first surface 111 and/or the second surface 112 will be referred to as a horizontal direction, and a direction substantially perpendicular to the first surface 111 and/or the second surface 112 will be referred to as a vertical direction.

The first region R1 of the lower semiconductor substrate 110 may correspond to a circuit region in which a circuit performing a predetermined function is disposed. The second region R2 may be a region other than the circuit region R1, and may be, for example, a dummy region. The second region R2 may be disposed outside the first region R1 and adjacent to the first region R1. For example, as shown, the second region R2 may be located on the right side of the first region R1.

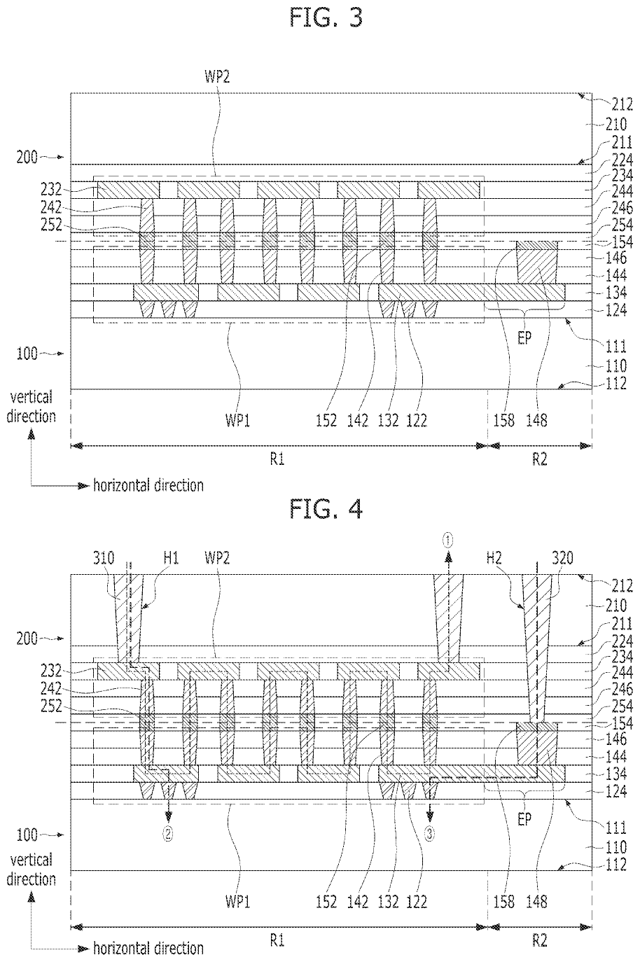

The lower circuit structure WP1 may be disposed over the first surface 111 of the first region R1 of the lower semiconductor substrate 110. The lower circuit structure WP1 may include circuits performing various functions, and may be formed of a combination of one or more insulating layers and one or more conductive layers. In the present embodiment, the lower circuit structure WP1 may include a conductive structure forming a daisy chain connection structure (for example, in series or one after another) together with a conductive structure of an upper circuit structure W2 shown in FIG. 2. As an example, the lower circuit structure WP1 may include a connection pattern 122, a lower conductive pad 132, and a lower conductive via 142 that are vertically stacked from the first surface 111 of the lower semiconductor substrate 110.

One or more lower conductive pads 132 may be formed. When a plurality of lower conductive pads 132 are formed, they may be arranged to be spaced apart from each other in the horizontal direction while being positioned at the same level in the vertical direction. Although the case in which four lower conductive pads 132 are arranged in the horizontal direction has been described in the embodiment illustrated in FIG. 1, the present disclosure is not limited thereto, and various modifications may be made on the premise that the number of the lower conductive pads 132 is one or more. The lower conductive pad 132 may have a plate shape or a shape similar thereto in which a length in the vertical direction is relatively small compared to a length in the horizontal direction. Hereinafter, the length in the horizontal direction will be referred to as a width, and the length in the vertical direction will be referred to as a thickness. The widths and/or planar areas of the lower conductive pads 132 may be the same as each other, or at least one may be different from each other. For example, as shown in this drawing, the width of the lower conductive pad 132 located at one end, for example, at the right end, in the horizontal direction may be greater than the width of another lower conductive pad 132. This may be because the lower conductive pad 132 located at the right end extends to the second region R2 to be in contact with the dummy conductive via 148.

Two or more lower conductive vias 142 connected to each lower conductive pad 132 may be disposed over each lower conductive pad 132. The lower conductive vias 142 may be positioned at the same level in the vertical direction. The lower conductive vias 142 may each have a columnar shape. Columnar shape refers to a form that resembles a column which is vertical, elongated and has a width smaller than a height (also referred to as thickness). The lower conductive via 142 may each have a smaller width than the lower conductive pad 132. For example, the cross-section of the lower conductive via 142 may be cylindrical, however, the invention is not limited by the shape of the cross-section. Also, the lower conductive via 142 may have a constant area cross-section along its entire thickness or may have a slightly tapered cross-sectional area with the cross-sectional area at the bottom of the column being less than the cross-sectional area at the top of the column.

At least one connection pattern 122 connected to at least one lower conductive pad 132 may be disposed under the at least one lower conductive pad 132. In the present embodiment, the case where three connection patterns 122 are disposed under each of two lower conductive pads 132 positioned at both ends in the horizontal direction has been described, but the present disclosure is not limited thereto, and the position and number of the lower conductive pads 132 may be variously modified as long as the connection pattern 122 electrically connects at least one lower conductive pad 132 and the lower semiconductor substrate 110. The connection pattern 122 may have a columnar shape, and may have a smaller width than the lower conductive pad 132. For example, the cross-section of the connection pattern 122 may be cylindrical, however, the invention is not limited by the shape of the cross-section. Also, the connection pattern 122 may have a tapered cross-sectional area with the cross-sectional area at the bottom of the column being less than the cross-sectional area at the top of the column.

The connection pattern 122, the lower conductive pad 132, and the lower conductive via 142 may be buried in the multi-layer insulating interlayer 124, 134, 144, and 146. In the present embodiment, four interlayer insulating layers 124, 134, 144, and 146 are shown, but the number of the interlayer insulating layers may be variously modified. For example, the connection pattern 122 and the lower conductive pad 132 may be buried in the insulating interlayers 124, and 134, respectively, and the lower conductive via 142 may be buried in the insulating interlayers 144, and 146.

According to the illustrated embodiment of FIG. 1, the lower circuit structure WP1 is disposed in the first region R1 and may include, as an example, the connection patterns 122, the lower conductive pads 132, and the lower conductive vias 142. Furthermore, although not shown, the lower circuit structure WP1 may include other circuits that are variously implemented according to the function or type of the lower semiconductor structure 100, in addition to the connection patterns 122, the lower conductive pads 132, and the lower conductive vias 142. For example, when the lower semiconductor structure 100 is a memory chip including a volatile memory such as DRAM (Dynamic Random Access Memory) or SRAM (Static RAM), a non-volatile memory such as NAND flash, RRAM (Resistive RAM), PRAM (Phase-change RAM), MRAM (Magneto-resistive RAM), or FRAM (ferroelectric RAM), or the like, the lower circuit structure WP1 may include a memory cell array including a plurality of memory cells. Alternatively, for example, when the lower semiconductor structure 100 is a logic chip or controller including a peripheral circuit for driving a memory, the lower circuit structure WP1 may include the peripheral circuit.

The lower conductive pad 132 positioned at one end, for example, at the right end, among the plurality of lower conductive pads 132 of the lower circuit structure WP1, may further extend from the first region R1 to the second region R2. A portion of the lower conductive pad 132 at the right end, which overlaps the second region R2, will be referred to as an extended portion EP of the lower conductive pad 132 hereinafter.

The dummy conductive via 148 may be disposed over the second region R2, and may be connected to the extended portion EP of the lower conductive pad 132. The dummy conductive via 148 may be formed together during the process of forming the lower conductive vias 142. Accordingly, the dummy conductive via 148 may be positioned at the same level as the lower conductive vias 142 in the vertical direction, and may be formed of the same material and same height in the vertical direction as the lower conductive vias 142. However, the width of the dummy conductive via 148 may be greater than the width of each of the lower conductive vias 142. For example, the width of the upper surface of the dummy conductive via 148 may be greater than the width of the upper surface of each of the lower conductive vias 142.

Each one of the lower bonding pads 152 may be formed over a corresponding lower conductive via 142 and may overlap and connect to the corresponding one of the lower conductive vias 142. Each lower bonding pad 152 may be coextensive in the horizontal direction with its corresponding lower conductive via 142. Accordingly, the arrangement of the lower bonding pads 152 may be the same as the arrangement of the lower conductive vias 142. In the present embodiment, the case where the lower bonding pads 152 have the same width as the upper surface of the lower conductive vias 142 is shown, but the present disclosure is not limited thereto, and the widths of the lower bonding pads 152 and the lower conductive vias 142 may be different from each other on the premise that the lower bonding pads 152 and the lower conductive vias 142 overlap and connect to each other. The lower bonding pads 152 may be for electrically connecting the lower semiconductor structure 100 to an upper semiconductor structure (see 200 in FIG. 2) to be described later. The lower bonding pads 152 may include various conductive materials, and may have a single layer structure or a multilayer structure. In particular, when the lower bonding pads 152 are directly bonded to an upper bonding pad (refer to 252 in FIG. 2) of an upper semiconductor structure to be described later to form a hybrid-bonding structure, the lower bonding pads 152 may include a metal material that can be combined with the upper bonding pad by interdiffusion of metals through a high-temperature annealing process. For example, the lower bonding pads 152 may include a metal such as copper (Cu), nickel (Ni), tin (Sn), gold (Au), or silver (Ag), an alloy including the metal, or a compound of the metal.

The dummy conductive pad 158 may be formed to overlap and connect to the dummy conductive via 148 over the dummy conductive via 148. In the present embodiment, the dummy conductive pad 158 has the same width as the upper surface of the dummy conductive via 148, but the present disclosure is not limited thereto, and the widths of the dummy conductive pad 158 and the dummy conductive via 148 may be different from each other on the premise that the dummy conductive pad 158 and the dummy conductive via 148 overlap and connect each other. The dummy conductive pad 158 may be formed together during the process of forming the lower bonding pad 152. Accordingly, the dummy conductive pad 158 may be positioned at the same level as the lower bonding pad 152 in the vertical direction, and may be formed of the same material as the lower bonding pad 152. However, the width of the dummy conductive pad 158 may be greater than the width of the lower bonding pad 152 at the same height in the vertical direction. For example, the width of the upper surface of the dummy conductive pad 158 may be greater than the width of the upper surface of the lower bonding pad 152. The width of the upper surface of the lower bonding pad 152 will be referred to as a first width W1, and the width of the upper surface of the dummy conductive pad 158 will be referred to as a second width W2.

The lower insulating layer 154 may be formed over the lower circuit structure WP1 and the dummy conductive via 148 to fill a space between the lower bonding pads 152 and between the lower bonding pad 152 and the dummy conductive pad 158 adjacent to each other. That is, the lower insulating layer 154 may be positioned at the same level as the lower bonding pads 152 and the dummy conductive pad 158 in the vertical direction. The lower insulating layer 154 may include various insulating materials. In particular, when the lower insulating layer 154 is directly bonded to an upper insulating layer (see 254 in FIG. 2) of an upper semiconductor structure (see 200 in FIG. 2) to be described later to form a hybrid-bonding structure, the lower insulating layer 154 may include an insulating material capable of being combined with the upper insulating layer by covalent bonding between the insulating materials. For example, the lower insulating layer 154 may include silicon oxide or silicon nitride.

FIG. 2 is a simplified cross-sectional view illustrating an upper semiconductor structure according to an embodiment of the present disclosure.

Referring to FIG. 2, an upper semiconductor structure 200 of the present embodiment may include an upper semiconductor substrate 210 including a first region R1 and a second region R2, an upper circuit structure WP2 disposed over the first region R1 of the upper semiconductor substrate 210, one or more upper bonding pads 252 connected to the upper circuit structure WP2 over the upper circuit structure WP2, and an upper insulating layer 254 filled between the upper bonding pads 252.

The upper semiconductor substrate 210 may include a semiconductor material such as silicon or germanium, and may have a first surface 211, and a second surface 212 opposite to each other in the thickness direction, and a side surface. The first surface 211 may correspond to a front surface and/or an active surface on which the upper circuit structure WP2 is disposed, and the second surface 212 may correspond to a rear surface and/or an inactive surface located opposite to the front surface and/or the active surface.

The upper circuit structure WP2 may be disposed over the first surface 211 of the first region R1 of the upper semiconductor substrate 210. The upper circuit structure WP2 may include circuits performing various functions, and may be formed of a combination of one or more insulating layers and one or more conductive layers. In the present embodiment, the upper circuit structure WP2 may include a conductive structure forming a daisy chain connection structure together with the lower circuit structure (see WP1 in FIG. 1). As an example, the upper circuit structure WP2 may include an upper conductive pad 232 and an upper conductive via 242 that are vertically stacked from the first surface 211 of the upper semiconductor substrate 210.

A plurality of upper conductive pads 232 may be formed. The plurality of upper conductive pads 232 may be spaced apart from each other in the horizontal direction while being positioned at the same level in the vertical direction. In the present embodiment, the case where five upper conductive pads 232 are arranged in the horizontal direction has been described, but the present disclosure is not limited thereto, and the number of the upper conductive pads 232 may be variously modified. The upper conductive pad 232 may have a plate shape or a shape similar thereto. The widths and/or planar areas of the upper conductive pads 232 may be the same as each other or at least one may be different from each other. For example, as shown in FIG. 2, the five upper conductive pads 232 may have the same size.

Two upper conductive vias 242 connected to each upper conductive pad 232 may be disposed over each upper conductive pad 232, except for two upper conductive pads 232 positioned at both ends in the horizontal direction. At least one upper conductive via 242 may be connected to each of the two upper conductive pads 232 positioned at both ends in the horizontal direction thereover. As will be described later, the two upper conductive pads 232 positioned at both ends in the horizontal direction may correspond to the start and end points of the daisy chain, respectively, and thus, it may be sufficient to be electrically connected to a corresponding lower conductive pad 132. A plurality of upper conductive vias 242 may be positioned at the same level in the vertical direction. The upper conductive via 242 may have a columnar shape, and may have a smaller width than the upper conductive pad 232.

The upper conductive pad 232 and the upper conductive via 242 may be buried in the multi-layer insulating interlayer 224, 234, 244, and 246. Here, the upper conductive pad 232 may be formed over a lowermost interlayer insulating layer 224 to be electrically insulated from the upper semiconductor substrate 210. In the present embodiment, four interlayer insulating layers 224, 234, 244, and 246 are shown, but the number of the interlayer insulating layers may be variously modified.

According to the illustrated embodiment of FIG. 2, the upper circuit structure WP2 is disposed in the first region R1 may include, for example, the upper conductive pad 232 and the upper conductive via 242. The upper circuit structure WP2 may further include circuits and/or wiring structures implemented in various ways according to the function or type of the upper semiconductor structure 200, in addition to the upper conductive pad 232 and the upper conductive via 242. For example, when the upper semiconductor structure 200 is a memory chip including a volatile memory or a non-volatile memory, the upper circuit structure WP2 may include a memory cell array including a plurality of memory cells. Alternatively, for example, when the upper semiconductor structure 200 is a logic chip or controller including a peripheral circuit for driving a memory, the upper circuit structure WP2 may include the peripheral circuit. The upper semiconductor structure 200 may have the same type as the lower semiconductor structure 100. For example, the lower and upper semiconductor structures 100 and 200 may include the same type of memory. Alternatively, the upper semiconductor structure 200 may have a different type from the lower semiconductor structure 100. For example, the lower and upper semiconductor structures 100 and 200 may include different types of memories, or one of the lower and upper semiconductor structures 100 and 200 may include a memory and the other may include a peripheral circuit.

The upper bonding pad 252 may be formed to overlap and connect to each upper conductive via 242 over each upper conductive via 242. Accordingly, the arrangement of the upper bonding pads 252 may be the same as the arrangement of the upper conductive vias 242. In the present embodiment, the case where the upper bonding pad 252 has the same width as the upper surface of the upper conductive via 242 is shown, but the present disclosure is not limited thereto, and the widths of the upper bonding pad 252 and the lower conductive via 242 may be different from each other on the premise that the upper bonding pad 252 and the lower conductive via 242 overlap and connect each other. The upper bonding pad 252 may be for electrically connecting the upper semiconductor structure 200 to the aforementioned lower semiconductor structure (see 100 in FIG. 1). The upper bonding pad 252 may include various conductive materials, and may have a single layer structure or a multilayer structure. In particular, when the upper bonding pad 252 is directly bonded to the lower bonding pad (see 152 in FIG. 1) of the lower semiconductor structure described above to form a hybrid-bonding structure, the upper bonding pad 252 may include a metal material that can be combined with the lower bonding pad by interdiffusion of metals through a high-temperature annealing process. For example, the upper bonding pad 252 may include a metal such as copper (Cu), nickel (Ni), tin (Sn), gold (Au), or silver (Ag), an alloy including the metal, or a compound of the metal.

The upper insulating layer 254 may be formed to fill a space between the upper bonding pads 252 over the upper circuit structure WP2. The upper insulating layer 254 may include various insulating materials. In particular, when the upper insulating layer 254 is directly bonded to the lower insulating layer (see 154 in FIG. 1) of the lower semiconductor structure (see 100 in FIG. 1) to form a hybrid-bonding structure, the upper insulating layer 254 may include an insulating material capable of being combined with the lower insulating layer by a covalent bond between insulating materials. For example, the upper insulating layer 254 may include silicon oxide or silicon nitride.

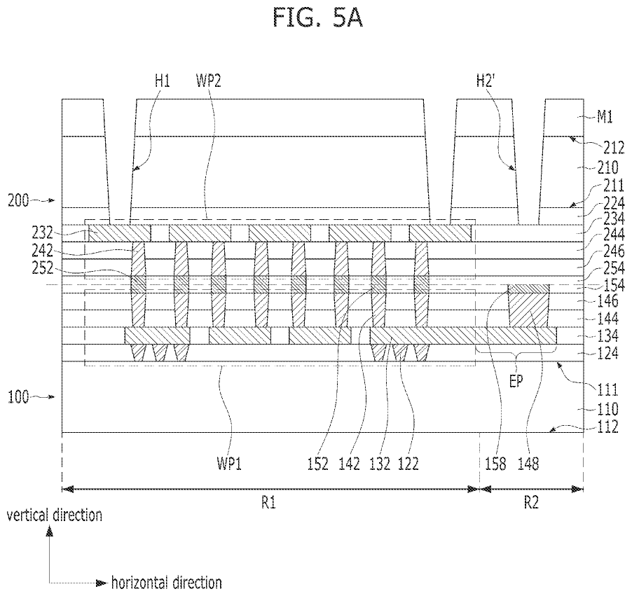

The lower semiconductor structure 100 and the upper semiconductor structure 200 described above may be bonded to each other in a state that the lower bonding pad 152 and the upper bonding pad 252 face each other, and the lower insulating layer 154 and the upper insulating layer 254 face each other. As an example, the upper semiconductor structure 200 may be disposed over and bonded to the lower semiconductor structure 100 in an upside-down state so that the first surface 211 of the upper semiconductor substrate 210 faces down and the second surface 212 faces up. An example of this is described with reference to FIG. 3.

FIG. 3 is a simplified cross-sectional view illustrating a semiconductor device in a state in which the lower semiconductor structure of FIG. 1 and the upper semiconductor structure of FIG. 2 are stacked.

Referring to FIG. 3, the semiconductor device of the present embodiment may include a lower semiconductor structure 100 and an upper semiconductor structure 200 disposed over the lower semiconductor structure 100. In the present embodiment, the vertical position of the upper semiconductor structure 200 may be reversed compared to FIG. 2.

The upper bonding pad 252 of the upper semiconductor structure 200 may be directly bonded to the lower bonding pad 152 of the lower semiconductor structure 100, and the upper insulating layer 254 of the upper semiconductor structure 200 may be directly bonded to the lower insulating layer 154 of the lower semiconductor structure 100. The semiconductor device may be formed by performing a high-temperature annealing process in a state where the lower bonding pad 152 and the lower insulating layer 154 of the lower semiconductor structure 100 are in contact with the upper bonding pad 252 and the upper insulating layer 254 of the upper semiconductor structure 200, respectively. During the high-temperature annealing process, the lower bonding pad 152 and the upper bonding pad 252 may be bonded to each other by interdiffusion of metals, for example, copper, for forming the lower bonding pad 152 and the upper bonding pad 252. That is, the lower bonding pad 152 and the upper bonding pad 252 may form a metal-to-metal bond. In this process, the lower insulating layer 154 and the upper insulating layer 254 may be combined with each other by covalent bonding formed between insulating materials, for example, silicon oxide or silicon nitride, for forming the lower insulating layer 154 and the upper insulating layer 254. That is, the lower insulating layer 154 and the upper insulating layer 254 may form an insulator-to-insulator bond. Thus, a hybrid bonding between the lower semiconductor structure 100 and the upper semiconductor structure 200, that is, the metal-to-metal bond and the insulator-to-insulator bond may be achieved.

The upper semiconductor structure 200 may not include a pad corresponding to the dummy conductive pad 158 of the lower semiconductor structure 100, and thus, the upper surface of the dummy conductive pad 158 may be in contact with the upper insulating layer 254.

Here, the lower conductive pads 132, the lower conductive vias 142, the lower bonding pads 152, the upper bonding pads 252, the upper conductive vias 242, and the upper conductive pads 232 may form a daisy chain.

More specifically, each lower conductive pad 132 may be electrically connected to one upper conductive pad 232 through one lower conductive via 142 connected thereto, one lower bonding pad 152 connected to the one lower conductive via 142, one upper bonding pad 252 connected to the one lower bonding pad 152, and one upper conductive via 242 connected to the one upper bonding pad 252, while being electrically connected to another upper conductive pad 232 through another lower conductive via 142 connected thereto, another lower bonding pad 152 connected to the another lower conductive via 142, another upper bonding pad 252 connected to the another lower bonding pad 152, and another upper conductive via 242 connected to the another upper bonding pad 252.

Here, the one upper conductive pad 232 and the another upper conductive pad 232 to which each lower conductive pad 132 is simultaneously connected may be adjacent to each other. For example, each lower conductive pad 132 may be electrically connected to a left upper conductive pad 232 through a left conductive via 142, a left lower bonding pad 152, a left upper bonding pad 252, and a left upper conductive via 242, while being electrically connected to a right upper conductive pad 232 through a right lower conductive via 142, a right lower bonding pad 152, a right upper bonding pad 252, and a right upper conductive via 242.

Similarly, except for the two upper conductive pads 232 positioned at both ends, each of remaining upper conductive pads 232 may be electrically connected to one lower conductive pad 132 through one upper conductive via 242 connected thereto, one upper bonding pad 252 connected to the one upper conductive via 242, one lower bonding pad 152 connected to the one upper conductive pad 252, and one lower conductive via 142 connected to the one lower bonding pad 152, while electrically connected to another lower conductive pad 132 through another upper conductive via 242 connected thereto, another upper bonding pad 252 connected to the another upper conductive via 242, another lower bonding pad 152 connected to the another upper conductive pad 252, and another lower conductive via 142 connected to the another lower bonding pad 152. Here, the one lower conductive pad 132 and the another lower conductive pad 132 to which each of the remaining upper conductive pads 232 are simultaneously connected may be adjacent to each other. For example, each of the remaining upper conductive pads 232 may be electrically connected to a left lower conductive pad 132 through a left upper conductive via 242, a left upper bonding pad 252, a left lower bonding pad 152, and a left lower conductive via 142, while being electrically connected to a right lower conductive pad 132 through a right upper conductive via 242, a right upper bonding pad 252, a right lower bonding pad 152, and a right lower conductive via 142.

The two upper conductive pads 232 located at both ends may correspond to the start and end points of the daisy chain, respectively. One of the two upper conductive pads 232, for example, the upper conductive pad 232 positioned at a left end may be electrically connected to the lower conductive pad 132 at the left end through one upper conductive via 242 connected thereto, one upper bonding pad 252 connected to the one upper conductive via 242, one lower bonding pad 152 connected to the one upper bonding pad, and one lower conductive via 142 connected to the one lower bonding pad 152, and the other of the two upper conductive pads 232, for example, the upper conductive pad 232 positioned at a right end may be electrically connected to the lower conductive pad 132 at the right end through one upper conductive via 242 connected thereto, one upper bonding pad 252 connected to the one upper conductive via 242, one lower bonding pad 152 connected to the one upper bonding pad, and one lower conductive via 142 connected to the one lower bonding pad 152.

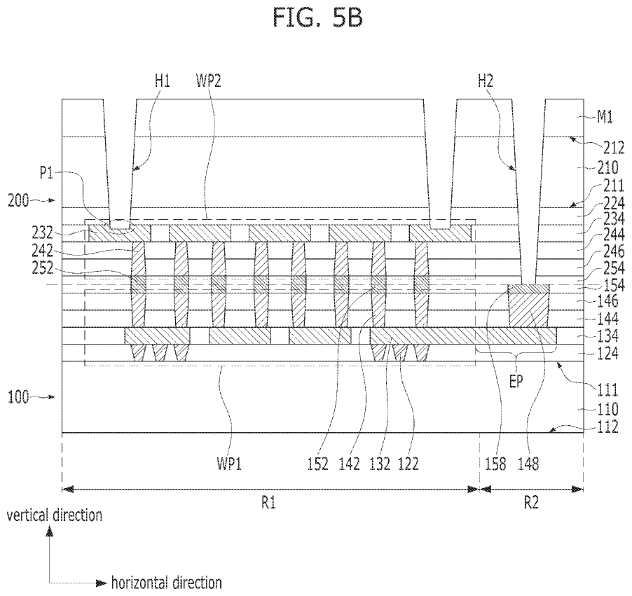

This daisy chain may be formed to verify whether the lower semiconductor structure 100 and the upper semiconductor structure 200 are normally aligned and/or whether an electrical connection between them is normally made. When the plurality of lower bonding pads 152 of the lower semiconductor structure 100 and the plurality of upper bonding pads 252 of the upper semiconductor structure 200 are respectively bonded and connected to each other, current flow through the daisy chain may be possible. In this case, it may be determined that the lower semiconductor structure 100 and the upper semiconductor structure 200 are normally aligned. It may be necessary to form through electrodes respectively connected to the two upper conductive pads 232 positioned at both ends in addition to the semiconductor device of FIG. 3, in order to verify whether current flows through the daisy chain. Furthermore, it may be further necessary to form a dummy through electrode in order to easily remove charges generated when forming the through electrode. An example of this is described with reference to FIG. 4.

FIG. 4 is a simplified cross-sectional view illustrating a semiconductor device in a state in which a through electrode and a dummy through electrode are further formed in addition to the semiconductor device of FIG. 3.

Referring to FIG. 4, the semiconductor device of the present embodiment may further include two through electrodes 310 spaced apart from each other in the horizontal direction in the first region R1 and a dummy through electrode 320 in the second region R2, in addition to the semiconductor device of FIG. 3. The two through electrodes 310 may pass through the upper semiconductor substrate 210 and the interlayer insulating layer 224 to be respectively connected to the two upper conductive pads 232 positioned at both opposite ends in the first region R1 in the horizontal direction. The dummy through electrode 320 may pass through the upper semiconductor structure 200 to be connected to the dummy conductive pad 158 in the second region R2.

The through electrode 310 may have a columnar shape having an upper surface exposed from the second surface 212 of the upper semiconductor substrate 210 and a lower surface connected to the upper conductive pad 232. As an example, the through electrode 310 may include a through silicon via (TSV). Also, the through electrode 310 may include various conductive materials. As an example, the through electrode 310 may include a metal such as copper (Cu), tin (Sn), silver (Ag), tungsten (W), nickel (Ni), ruthenium (Ru), and cobalt (Co), or a compound of this metal.

When different voltages are applied to the two through electrodes 310, a first current flow (see dotted line arrow (1) flows from one through electrode 310 toward the other through electrode 310 via the daisy chain. The first current flow may be formed when each of the plurality of lower bonding pads 152 is normally bonded and connected to a corresponding upper bonding pad 252. If at least one of the plurality of lower bonding pads 152 is not connected to a corresponding upper bonding pad 252, the first current flow may be cut off. When the first current flow is formed, it confirms that a proper alignment between the lower semiconductor structure 100 and the upper semiconductor structure 200 is made. Conversely, when the first current flow is not formed, it means that the lower semiconductor structure 100 and the upper semiconductor structure 200 are misaligned.

The dummy through electrode 320 may pass through the upper semiconductor structure 200 in the second region R2 to be connected to the dummy conductive pad 158. The dummy through electrode 320 may have a columnar shape having an upper surface exposed from the second surface 212 of the upper semiconductor substrate 210 and a lower surface connected to the dummy conductive pad 158. As an example, the dummy through electrode 320 may include a TSV. Also, the dummy through electrode 320 may include various conductive materials. As an example, the dummy through electrode 320 may include a metal such as copper (Cu), tin (Sn), silver (Ag), tungsten (W), nickel (Ni), ruthenium (Ru), and cobalt (Co), or a compound of this metal. The dummy through electrode 320 may be formed of the same material as the through electrode 310.

The through electrode 310 may be formed by forming a first hole H1 exposing the upper conductive pad 232 by etching the upper semiconductor substrate 210 and the interlayer insulating layer 224 from the second surface 212 of the upper semiconductor substrate 210, and filling the first hole H1 with a conductive material. In addition, the dummy through electrode 320 may be formed by forming a second hole H2 exposing the dummy conductive pad 158 by etching the upper semiconductor substrate 210, the interlayer insulating layers 224, 234, 244, and 246, and the upper insulating layer 254 from the second surface 212 of the upper semiconductor substrate 210, and filling the second hole H2 with a conductive material. In this case, a large amount of charges may be generated during an etching process for forming the first hole H1 and the second hole H2. These charges may escape to the lower semiconductor substrate 110 through the through electrode 310, the upper conductive pad 232, the upper conductive via 242, the upper bonding pad 252, the lower bonding pad 152, the lower conductive via 142, the lower conductive pad 132, and the connection pattern 122, and the flow of these charges will be referred to as a second current flow (see a dotted line arrow \textcircled{2}). In addition, these charge may escape to the lower semiconductor substrate 110 through the dummy through electrode 320, the dummy conductive pad 158, the dummy conductive via 148, the lower conductive pad 132, and the connection pattern 122, and the flow of these charges will be referred to as a third current flow (see a dotted line arrow \textcircled{3}). That is, the charges generated in the etching process may escape through the second current flow and/or the third current flow.

The advantages of the present embodiment may be described as follows in comparison with a comparative example.

In the comparative example, a dummy through electrode, a dummy conductive pad, a dummy conductive via may be omitted, and thus, only a second current flow may exist. In the comparative example, if lower and upper bonding pads on the second current flow are not connected to each other because a lower semiconductor structure and an upper semiconductor structure are misaligned, the second current flow may be cut off. When the second current flow is cut off, charges generated in an etching process for forming a through electrode cannot escape to a lower semiconductor substrate, and thus a kind of bursting phenomenon called arcing may occur. In this case, a semiconductor device may become a defective structure that can no longer be used.

On the other hand, in the present embodiment, although the lower semiconductor structure 100 and the upper semiconductor structure 200 are misaligned so that the lower bonding pad 152 and the upper bonding pad 252 on the second current flow are not connected to each other, the charges generated in the etching process for forming the through electrode 310 and the dummy through electrode 320 may escape to the lower semiconductor substrate 110 through the third current flow. Even if the lower bonding pad 152 and the upper bonding pad 252 are misaligned and do not contact each other, the dummy conductive pad 158 may have a relatively larger width than the lower bonding pad 152, and thus, the dummy through electrode 320 may easily contact and connect with the dummy conductive pad 158. As a result, an arcing phenomenon may not occur, and defects of the semiconductor device may be prevented.

FIGS. 1 to 4 have described the case where the lower circuit structure WP1 and the upper circuit structure WP2 include conductive structures for forming the daisy chain, but the present disclosure is not limited thereto. Each of the lower circuit structure WP1 and the upper circuit structure WP2 may include another circuit that performs a predetermined function, and even in this case, the present disclosure may be possible when the through electrode 310 is electrically connected to the upper circuit structure WP2 and the dummy through electrode 320 is electrically connected to a part of the lower circuit structure WP1 through the dummy conductive pad 158 and the dummy conductive via 148 so that the transfer of charges to the lower semiconductor substrate 110 is possible through the dummy through electrode 320, the dummy conductive pad 158, the dummy conductive via 148, and the lower circuit structure WP1.

Also, in the present embodiment, the dummy conductive pad 158 is formed together with the lower bonding pad 152, and the dummy conductive via 148 is formed together with the lower conductive via 142, but the present disclosure is not limited thereto. The dummy conductive pad 158 and the dummy conductive via 148 may be formed separately from the lower bonding pad 152 and the lower conductive via 142. In addition, one dummy conductive pattern integrally formed may be used instead of the dummy conductive pad 158 and the dummy conductive via 148. Even in this case, the upper surface of the dummy conductive pattern may be positioned at the same level as the upper surface of the lower bonding pad 152 in the vertical direction, and may have a width greater than the first width W1 of the upper surface of the lower bonding pad 152.

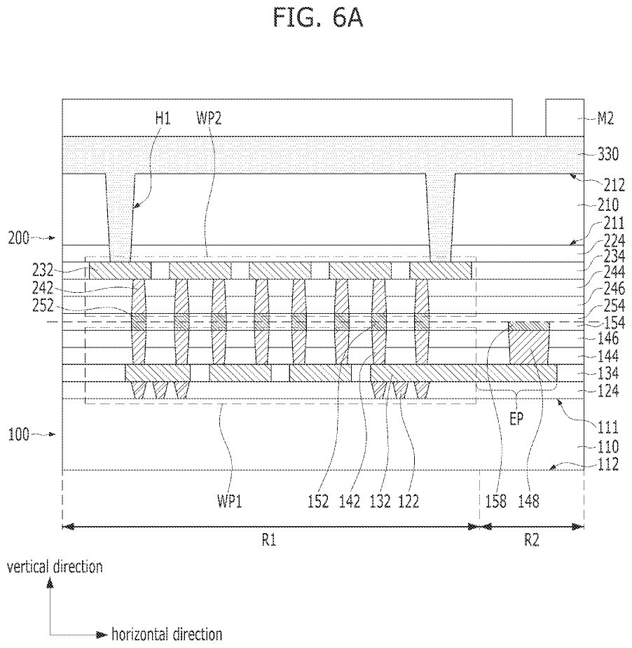

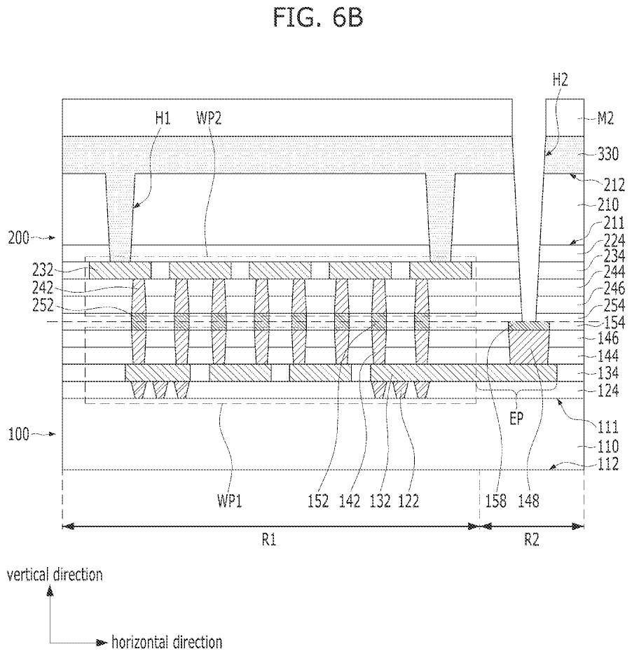

Meanwhile, a method of forming the first hole H1 and the second hole H2 of FIG. 4 will be described in more detail with reference to FIGS. 5A to 6B below.

FIGS. 5A and 5B are cross-sectional views illustrating a method for fabricating a semiconductor device according to an embodiment of the present disclosure, and in particular, an example of a method for forming the first hole H1 and the second hole H2 of FIG. 4.

Referring to FIG. 5A, a mask pattern M1 may be formed over the resultant structure of FIG. 3 to expose portions where the first and second holes H2 are to be formed and cover the remaining portions. Then, first etching may be performed until the upper surface of the upper conductive pad 232 is exposed using the mask pattern M1 as an etching barrier.

As a result of the first etching, the first hole H1 exposing the upper surface of the upper conductive pad 232 may be formed. On the other hand, since the second hole H2 has a greater depth than the first hole H1, the formation of the second hole H2 may not be completed during the first etching, and an initial second hole H2′ having a small depth than the second hole H2 may be formed. The initial second hole H2′ may have substantially the same depth as the first hole H1 or may have a slightly greater depth than the first hole H1.

Referring to FIG. 5B, secondary etching may be performed using the mask pattern M1 as an etching barrier until the upper surface of the dummy conductive pad 158 is exposed.

As a result of the secondary etching, the interlayer insulating layers 234, 244, and 246, and the upper insulating layer 254 under the initial second hole H2′ may be etched to form the second hole H2. In this case, a portion of the upper conductive pad 232 exposed through the first hole H1 may be lost due to over-etching. Accordingly, the upper conductive pad 232 may have a shape in which a portion exposed by the first hole H1 is depressed. In other words, the height of the portion of the upper surface of the upper conductive pad 232 exposed by the first hole H1 may be lower than the height of the remaining portion.

Subsequently, the mask pattern M1 may be removed. Then, a semiconductor device identical to or similar to that shown in FIG. 4 may be obtained by performing subsequent processes, for example, a forming process of a conductive material having a thickness sufficient to fill the first hole H1 and the second hole H2, and a planarization process, for example, chemical mechanical polishing (CMP), to the conductive material until the second surface 212 of the upper semiconductor substrate 210 is exposed.

FIGS. 6A and 6B are cross-sectional views illustrating a method for fabricating a semiconductor device according to another embodiment of the present disclosure, and in particular, another example of a method for forming the first hole H1 and the second hole H2 of FIG. 4.

Referring to FIG. 6A, a mask pattern may be formed over the resultant structure of FIG. 3 to expose a portion where the first hole H1 is to be formed and cover the remaining portion. Then, the first hole H1 may be formed by performing first etching using the mask pattern as an etching barrier, until the upper surface of the conductive pad 232 is exposed.

Subsequently, a sacrificial layer 330 having a thickness sufficient to fill the first hole H1 may be formed, and then, a mask pattern M2 may be formed over the sacrificial layer 330 to expose a portion where the second hole H2 is to be formed. The sacrificial layer 330 may be formed of a material that can be removed during a removal process of the mask pattern M2. For example, when the mask pattern M2 includes a photoresist pattern, the sacrificial layer 330 may include a carbon-containing material.

Referring to FIG. 6B, the second hole H2 may be formed by performing secondary etching using the mask pattern M2 as an etching barrier until the upper surface of the dummy conductive pad 158 is exposed. During the secondary etching, since the first hole H1 is filled by the sacrificial layer 330, loss of the upper conductive pad 232 due to the secondary etching may not occur. In other words, the height of a portion of the upper surface of the upper conductive pad 232 exposed by the first hole H1 may be substantially the same as the height of the remaining portion.

Subsequently, the mask pattern M2 and the sacrificial layer 330 may be removed. The mask pattern M2 and the sacrificial layer 330 may be removed by a strip process using oxygen plasma. Then, a semiconductor device identical to or similar to that shown in FIG. 4 may be obtained by performing subsequent processes, for example, a forming process of a conductive material having a thickness sufficient to fill the first hole H1 and the second hole H2, and a planarization process to the conductive material until the second surface 212 of the upper semiconductor substrate 210 is exposed.

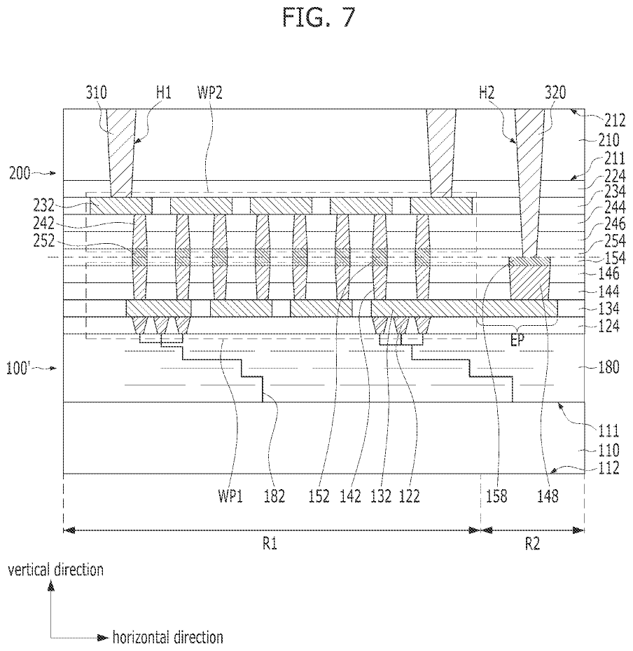

Meanwhile, in the above embodiments, the lower circuit structure WP1 of the lower semiconductor structure 100 may further include a memory cell array and/or a peripheral circuit, in addition to the connection pattern 122, the lower conductive pad 132, and the lower conductive via 142. In this case, the connection pattern 122 may directly contact the lower semiconductor substrate 110. However, the present disclosure is not limited thereto, and a memory cell array and/or a peripheral circuit may be disposed under the lower circuit structure WP1, and the connection pattern 122 may be connected to the lower semiconductor substrate 110 through the memory cell array and/or the peripheral circuit. This will be shown in FIG. 7.

FIG. 7 is a simplified cross-sectional view illustrating a semiconductor device according to another embodiment of the present disclosure. Differences from the above-described embodiments will be mainly described. Components identical to those of the above-described embodiments will be denoted using the same reference numerals.

Referring to FIG. 7, the lower semiconductor structure 100′ of the present embodiment may further include an additional circuit part 180 disposed below the lower circuit structure WP1.

The additional circuit part 180 may include a memory cell array and/or a peripheral circuit. The additional circuit part 180 may be formed of a combination of one or more insulating layers and one or more conductive layers. Conductive structures in the additional circuit part 180 are simply indicated by some lines. In particular, the additional circuit part 180 may include an additional conductive structure 182 connecting the connection pattern 122 and the lower semiconductor substrate 110. The additional conductive structure 182 may be formed of a combination of various conductive patterns extending in vertical and horizontal directions.

In this case, the connection pattern 122 may be connected to the lower semiconductor substrate 110 via the additional conductive structure 182 instead of directly contacting the lower semiconductor substrate 110.

According to the above embodiments of the present disclosure, it may be possible to provide a semiconductor device capable of preventing process defects and easily verifying alignment between two semiconductor structures, and a method for fabricating the same.

Although various embodiments have been described for illustrative purposes, it will be apparent to those skilled in the art that various changes and modifications may be made without departing from the spirit and scope of the present teachings as defined in the following claims.

What is claimed is:

1. A semiconductor device comprising:
a lower semiconductor structure including a lower semiconductor substrate including a first region and a second region adjacent to each other in a horizontal direction, a lower circuit structure disposed in the first region over the lower semiconductor substrate, a lower bonding pad disposed over the lower circuit structure and connected to the lower circuit structure, and a dummy conductive pattern disposed in the second region over the lower semiconductor substrate;
an upper semiconductor structure including an upper semiconductor substrate disposed over the lower semiconductor structure and including the first region and the second region, an upper circuit structure disposed in the first region under the upper semiconductor substrate, and an upper bonding pad disposed under the upper circuit structure and connected to the upper circuit structure while being bonded to the lower bonding pad;
a through electrode passing through the upper semiconductor substrate and connected to the upper circuit structure; and
a dummy through electrode passing through the upper semiconductor structure and connected to the dummy conductive pattern,
wherein the dummy through electrode and the dummy conductive pattern are electrically connected to the lower semiconductor substrate through the lower circuit structure.

2. The semiconductor device according to claim 1, wherein a width of an upper surface of the dummy conductive pattern is greater than a width of an upper surface of the lower bonding pad.

3. The semiconductor device according to claim 1, wherein the lower circuit structure includes a lower conductive pad disposed in the first region and having an extension portion extending to the second region, and a connection pattern connecting the lower conductive pad and the lower semiconductor substrate to each other and disposed between the lower conductive pad and the lower semiconductor substrate, and
the dummy conductive pattern is connected to the extension portion over the extension portion.

4. The semiconductor device according to claim 3, wherein a charge movement path to the lower semiconductor substrate is formed through the dummy through electrode, the dummy conductive pattern, the lower conductive pad, and the connection pattern.

5. The semiconductor device according to claim 3, wherein the lower circuit structure further includes a lower conductive via disposed between the lower conductive pad and the lower bonding pad, and
the dummy conductive pattern includes a dummy conductive via positioned at the same level as the lower conductive via in a vertical direction, and a dummy conductive pad positioned at the same level as the lower bonding pad in the vertical direction.

6. The semiconductor device according to claim 1, wherein the upper bonding pad and the lower bonding pad form a metal-to-metal bond.

7. The semiconductor device according to claim 1, wherein the lower semiconductor structure further includes a lower insulating layer filled between the lower bonding pad and another lower bonding pad,
the upper semiconductor structure further includes an upper insulating layer filled between the upper bonding pad and another upper bonding pad, and
the lower insulating layer and the upper insulating layer form an insulator-to-insulator bond.

8. The semiconductor device according to claim 7, wherein an upper surface of the dummy conductive pattern is in contact with the upper insulating layer.

9. The semiconductor device according to claim 1, wherein the lower circuit structure includes a lower conductive pad disposed over the lower semiconductor substrate and a lower conductive via disposed over the lower conductive pad and connected the lower conductive pad,
the lower bonding pad is disposed over the lower conductive via and connected thereto,
the upper circuit structure includes an upper conductive pad disposed under the upper semiconductor substrate and an upper conductive via disposed under the upper conductive pad and connected to the upper conductive pad,
the upper bonding pad is disposed under the upper conductive via and connected to the upper conductive via, and
the lower conductive pad, the lower conductive via, the upper conductive pad, and the upper conductive via are arranged to form a daisy chain.

10. The semiconductor device according to claim 9, wherein the through electrode includes two through electrodes respectively connected to two upper conductive pads corresponding to a start and an end of the daisy chain.

11. The semiconductor device according to claim 10, wherein an alignment of the lower semiconductor structure and the upper semiconductor structure is verified according to whether current flows through one of the two through electrodes, the daisy chain, and the other of the two through electrodes.

12. The semiconductor device according to claim 9, wherein the lower semiconductor structure further includes a connection pattern interposed between the lower conductive pad and the lower semiconductor substrate to electrically connect them.

13. The semiconductor device according to claim 12, wherein a charge movement path to the lower semiconductor substrate is formed through the through electrode, the daisy chain, and the connection pattern.

14. The semiconductor device according to claim 1, wherein the upper circuit structure includes an upper conductive pad, and the through electrode contacts an upper surface of the upper conductive pad.

15. The semiconductor device according to claim 14, wherein a height of a portion of the upper surface of the upper conductive pad, which is in contact with the through electrode, is lower than a height of a remaining portion.

16. The semiconductor device according to claim 3, wherein the connection pattern directly contacts the lower semiconductor substrate.

17. The semiconductor device according to claim 3, further comprising:
an additional conductive structure interposed between the lower semiconductor substrate and the connection pattern to connect the lower semiconductor substrate to the connection pattern.

18. A method for fabricating a semiconductor device, comprising:
providing a lower semiconductor structure including a lower semiconductor substrate including a first region and a second region, a lower circuit structure disposed in the first region over the lower semiconductor substrate, a lower bonding pad disposed over the lower circuit structure and connected the lower circuit structure, and a dummy conductive pattern disposed in the second region over the lower semiconductor substrate;
providing an upper semiconductor structure including an upper semiconductor substrate including the first region and the second region, an upper circuit structure disposed in the first region over the upper semiconductor substrate, and an upper bonding pad disposed over the upper circuit structure and connected to the upper circuit structure;
bonding the upper bonding pad to the lower bonding pad;
etching the upper semiconductor substrate to form a first hole exposing a portion of the upper circuit structure, and etching the upper semiconductor structure to form a second hole exposing the dummy conductive pattern; and
forming a through electrode and a dummy through electrode by filling the first hole and the second hole with a conductive material.

19. The method according to claim 18, wherein a width of an upper surface of the dummy conductive pattern is greater than a width of an upper surface of the lower bonding pad.

20. The method according to claim 18, wherein the upper circuit structure includes an upper conductive pad, and
the forming of the first hole is performed to expose an upper surface of the upper conductive pad.

21. The method according to claim 18, wherein the upper circuit structure includes an upper conductive pad, and
the forming of the first hole and the second hole includes:
forming a mask pattern over the upper semiconductor substrate to expose portions where the first hole and the second hole are to be formed;
forming the first hole by performing a first etching process using the mask pattern as an etching barrier until an upper surface of the upper conductive pad is exposed; and
forming the second hole by performing a secondary etching process using the mask pattern as an etching barrier until an upper surface of the dummy conductive pattern is exposed.

22. The method according to claim 21, wherein, during the secondary etching process, a portion of the upper conductive pad exposed by the first hole is over-etched.

23. The method according to claim 18, wherein the upper circuit structure includes an upper conductive pad, and
the forming of the first hole and the second hole includes:
forming a first mask pattern over the upper semiconductor substrate to expose a portion where the first hole is to be formed;
forming the first hole by performing a first etching process using the first mask pattern as an etching barrier until an upper surface of the upper conductive pad is exposed;
forming a sacrificial layer filling the first hole;
forming a second mask pattern over the sacrificial layer to expose a portion where the second hole is to be formed; and
forming the second hole by performing a secondary etching process using the second mask pattern as an etching barrier until an upper surface of the dummy conductive pattern is exposed.

24. The method according to claim 18, wherein the lower semiconductor structure further includes a lower insulating layer filled between the lower bonding pad and another lower bonding pad,
the upper semiconductor structure further includes an upper insulating layer filled between the upper bonding pad and another upper bonding pad, and
the upper insulating layer is bonded to the lower insulating layer in the bonding of the upper bonding pad to the lower bonding pad.

25. The method according to claim 24, wherein the upper insulating layer is in contact with an upper surface of the dummy conductive pattern.

26. The method according to claim 18, wherein the dummy through electrode and the dummy conductive pattern are electrically connected to the lower semiconductor substrate through the lower circuit structure.
